(19) United States
(12) Patent Application Publication
(10) Pub. No.: US 2026/0094640 A1
(43) Pub. Date: Apr. 2, 2026

(54) DISTRIBUTED READ DRIVER FOR DATA SENSING IN DYNAMIC RANDOM ACCESS MEMORY

(71) Applicant: Micron Technology, Inc., Boise, ID (US)

(72) Inventors: Rachit JAIN, Mumbai (IN); Naga Surya Anjan Kumar PUDI, Hyderabad (IN); Balaji JAYARAMAN, Hyderabad (IN)

(21) Appl. No.: 19/287,371

(22) Filed: Jul. 31, 2025

Related U.S. Application Data
(60) Provisional application No. 63/701,029, filed on Sep. 30, 2024.

(51) Int. Cl. G11C 11/4096; G11C 11/408; G11C 11/4091

(52) U.S. Cl. CPC G11C 11/4096; G11C 11/4091; G11C 11/4087

(57) ABSTRACT

A memory device includes a memory array and a sense amplifier circuit associated with the memory array for reading read data from the memory array. The sense amplifier circuit includes a local input/output (LIO)-global input/output (GIO) pulldown circuit and a GIO helper circuit. The LIO-GIO pulldown circuit is configured to transfer the read data from a differential pair of LIO lines to a differential pair of GIO lines. The LIO-GIO pulldown circuit is configured to amplify a difference between the differential pair of GIO lines. Additionally, the GIO helper circuit is configured to further amplify the difference between the differential pair of GIO lines.

### CROSS-REFERENCE TO RELATED APPLICATION

This patent application claims priority to U.S. Provisional Patent Application No. 63/701,029, filed on Sep. 30, 2024, entitled “DISTRIBUTED READ DRIVER FOR DATA SENSING IN DYNAMIC RANDOM ACCESS MEMORY,” and assigned to the assignee hereof. The disclosure of the prior Application is considered part of and is incorporated by reference into this patent application.

### TECHNICAL FIELD

The present disclosure generally relates to memory devices, memory device operations, and, for example, to data sensing in dynamic random access memory (DRAM).

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 is a diagrammatic view of an example memory device.

FIG. 2A shows a schematic diagram of a local input/output (LIO)-global input/output (GIO) pulldown circuit according to one or more implementations.

FIG. 2B shows a schematic diagram of a GIO helper circuit according to one or more implementations.

FIG. 3 shows a memory device according to one or more implementations.

FIG. 4 shows a memory device according to one or more implementations.

FIG. 5 is a flowchart of an example method associated with distributed read driver for data sensing in DRAM.

### DETAILED DESCRIPTION

In the field of DRAM technology, there is a constant drive toward higher densities and increased storage capacities. As DRAM densities exceed 16 gigabits (Gb), challenges associated with analog data timing (e.g., data access time tAA) from a memory array to a data output (e.g., DQ lines) during the reading of data from DRAM become more pronounced. However, addressing these timing challenges while maintaining efficient utilization of the die area and optimizing array efficiency is a technically complex endeavor.

For performing a read operation from a memory array, a voltage difference between a differential pair of global I/O (GIO) lines should be created that is strong enough that a data sense amplifier (DSA) of an I/O circuit can properly output a signal to rail voltages. For high density memory arrays, it becomes increasingly difficult to create a good delta voltage between the differential pair of GIO lines.

Current methods of managing data timing trade-offs often involve segmenting the DRAM array into smaller sections, increasing the size of a read driver within the DRAM array, or placing data sense amplifiers on both sides of the DRAM array. While these strategies might satisfy timing requirements, these strategies present significant drawbacks. Smaller array segments can hinder the density and capacity benefits of larger DRAM designs. Larger read drivers and additional sense amplifiers consume precious die area and can adversely impact an array efficiency of the DRAM device, an especially critical concern as densities increase. Moreover, these solutions can necessitate architectural alterations to existing DRAM designs, leading to increased design complexity and prolonged development cycles.

Therefore, a technical problem exists in finding a way to manage and optimize the analog data timing from a memory array to the data output (e.g., DQ lines) that allows for scaling DRAM densities without compromising die area, array efficiency, or necessitating extensive redesign of DRAM configurations. The sought after solution should achieve reduced data access time penalties for higher density designs, while also preserving, or even improving, overall DRAM efficiency and design agility.

Some implementations described herein improve analog data timing in high-density DRAM by introducing a distributed read driver architecture for data sensing. The distributed read driver architecture includes a memory array connected to a plurality of memory cells via a data input/output circuit for transmitting data and a differential pair of global I/O lines. Additionally, the distributed read driver architecture comprises various local I/O lines designed to receive read data and a read-write gap circuit that includes a local input/output (LIO)-global input/output (GIO) pulldown circuit and a GIO helper circuit. The LIO-GIO pulldown circuit is tasked with transferring read data from the LIO lines to the GIO lines and amplifying the difference between the GIO lines (e.g., a differential voltage). Moreover, the GIO helper circuit, incorporating a cross-coupled transistor circuit, further amplifies the difference between the GIO lines. In particular, the GIO helper circuit helps the LIO-GIO pulldown circuit to create a good differential voltage between the GIO lines that is provided to the DSA.

The distributed read driver structure may be modular, with each module associated with a sense amplifier circuit, and each sense amplifier circuit including respective LIO-GIO pulldown and GIO helper circuits. GIO helper circuits coupled to a same differential pair of GIO lines may be used in conjunction with each other to increase the differential voltage between the differential pair of GIO lines. In other words, while one GIO helper circuit may be associated with a particular sense amplifier circuit that is configured to sense data from a particular memory array, another GIO helper circuit associated with a different sense amplifier circuit of a different memory array may be used to further amplify the differential voltage between the differential pair of GIO lines so long as the other GIO helper circuit is coupled to the same differential pair of GIO lines. As a result, a series of GIO helper circuits along the differential pair of GIO lines may be used to ensure that the differential voltage between the differential pair of GIO lines is maintained strong enough to enable a DSA to properly output a signal to rail voltages. For example, a GIO helper circuit may be implemented in each p-channel metal-oxide-semiconductor (PMOS)-n-channel metal-oxide-semiconductor (NMOS) sense amplifier section or PMOS-NMOS sensor amplifier circuit region of the distributed read driver architecture. A PMOS-NMOS sensor amplifier may be referred to as a PNSA. The GIO helper circuits along the differential pair of GIO lines may be used to maintain a voltage difference or a PNSA height between the differential pair of GIO lines at an approximately same level along a length of the differential pair of GIO lines, ensuring that the DSA receives a large enough voltage delta on the differential pair of GIO lines to accurately process the voltage difference.

In this way, the distributed read driver architecture may mitigate the issue of increased analog data timing associated with higher DRAM densities. The incorporation of the GIO helper circuit alongside the LIO-GIO pulldown circuit may effectively reduce signal delay in reading data from the memory array by amplifying the difference between the GIO lines. Consequently, the distributed read driver architecture may improve signal integrity and timing margins of high-density DRAM devices.

In some implementations, a GIO helper circuit may be implemented in each PNSA section of the distributed read driver architecture with minimal circuit overhead, which will help build a good differential voltage at the DSA with minimum time, thus reducing tAA penalty. The distributed read driver architecture may allow the DSA to be implemented as an NMOS coupled DSA instead of a cross-coupled DSA, which may reduce a size of the DSA and save more die area.

The GIO helper circuit may include a plurality of pulldown transistors including: a first pulldown transistor having a first control gate coupled to a second GIO line of the differential pair of GIO lines and a first IO terminal coupled to a first GIO line of the differential pair of GIO lines; and a second pulldown transistor having a second control gate coupled to the first GIO line and a second IO terminal coupled to the second GIO line. The first GIO line may be configured to provide a first GIO voltage to the second control gate, and, based on the first GIO voltage exceeding a threshold voltage of the second pulldown transistor, the second pulldown transistor is configured to pull down the second GIO line such that the difference between the differential pair of GIO lines is increased. The second GIO line may be configured to provide a second GIO voltage to the first control gate, and, based on the second GIO voltage exceeding a threshold voltage of the first pulldown transistor, the first pulldown transistor is configured to pull down the first GIO line such that the difference between the differential pair of GIO lines is increased.

As a result, the distributed read driver architecture may allow DRAM densities to be scaled while conserving die area and maintaining core DRAM architecture. This optimized read driver design may decrease data access times and signal delays, which is pivotal in enhancing the overall operation speed and efficiency of high-density DRAM. In addition to performance benefits, the modular nature of the distributed read driver architecture may facilitate streamlined design processes for scaling DRAM technologies, thereby offering technical advantages in manufacturing throughput and resource conservation. By virtue of these technical enhancements, the inventive approach supports more efficient semiconductor device operation and reduces an amount of resources needed to support a market consuming high-density DRAM, such as raw materials, semiconductor manufacturing tools, labor, and computing resources.

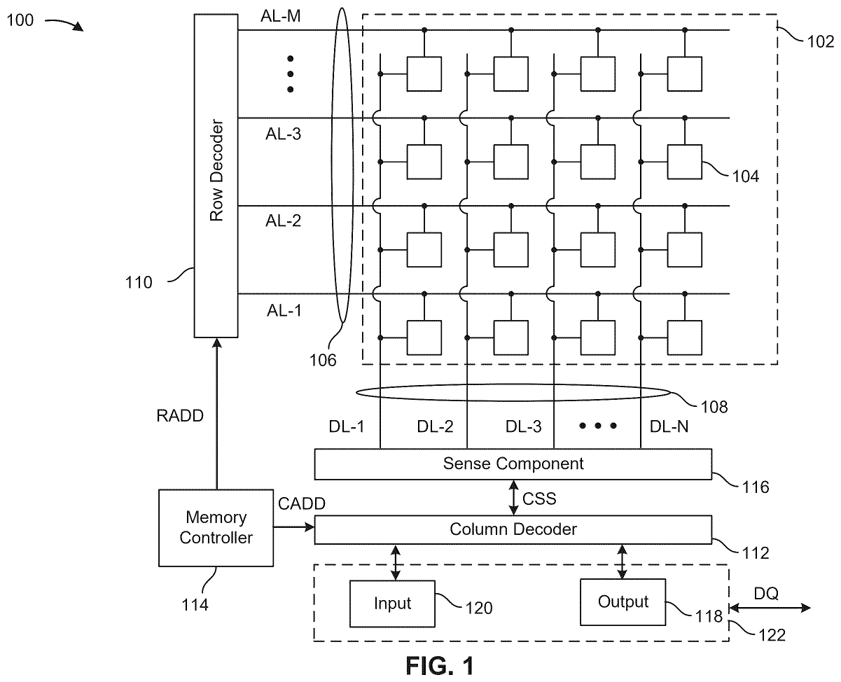

FIG. 1 is a diagrammatic view of an example memory device 100. The memory device 100 may include a memory array 102 that includes multiple memory cells 104. The memory array 102 may form a bank, a memory core, or a memory mat, or may be part of a bank. In some implementations, the memory device 100 may include a plurality of banks (e.g., a plurality of memory cores or memory mats), each formed by a respective memory array 102. A memory cell 104 is programmable or configurable into a data state of multiple data states (e.g., two or more data states). For example, a memory cell 104 may be set to a particular data state at a particular time, and the memory cell 104 may be set to another data state at another time. A data state may correspond to a value stored by the memory cell 104. The value may be a binary value, such as a binary 0 or a binary 1, or may be a fractional value, such as 0.5, 1.5, or the like. A memory cell 104 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 104 by activating or selecting the appropriate access line 106 (shown as access lines AL-1 through AL-M) and digit line 108 (shown as digit lines DL-1 through DL-N). An access line 106 may also be referred to as a “row line” or a “word line,” and a digit line 108 may also be referred to a “column line” or a “bit line.” Activating or selecting an access line 106 or a digit line 108 may include applying a voltage to the respective line. An access line 106 and/or a digit line 108 may comprise, consist of, or consist essentially of a conductive material, such as a metal (e.g., copper, aluminum, gold, titanium, or tungsten) and/or a metal alloy, among other examples. In FIG. 1, each row of memory cells 104 is connected to a single access line 106, and each column of memory cells 104 is connected to a single digit line 108. By activating one access line 106 and one digit line 108 (e.g., applying a voltage to the access line 106 and digit line 108), a single memory cell 104 may be accessed at (e.g., is accessible via) the intersection of the access line 106 and the digit line 108. The intersection of the access line 106 and the digit line 108 may be called an “address” of a memory cell 104.

In some implementations, the logic storing device of a memory cell 104, such as a cell capacitor, may be electrically isolated from a corresponding digit line 108 by a selection component, such as a cell transistor. The access line 106 may be connected to and may control the selection component. For example, the selection component may be a cell transistor, and the access line 106 may be connected to the gate of the cell transistor. Activating the access line 106 results in an electrical connection or closed circuit between the capacitor of a memory cell 104 and a corresponding digit line 108. The digit line 108 may then be accessed (e.g., is accessible) to either read from or write to the memory cell 104. In some implementations, the memory cells 104 may be DRAM memory cells.

A row decoder 110 and a column decoder 112 may control access to memory cells 104. Thus, the row decoder 110 and the column decoder 112 may each include control logic for generating control signals based on a received row address or a received column address, respectively. For example, the row decoder 110 may receive a row address RADD from a memory controller 114 and may activate the appropriate access line 106 based on the received row address RADD. For example, the row decoder 110 may enable one or more access lines 106 (e.g., word lines) based on a result obtained by decoding the row address RADD. The memory controller 114 may be part of a host device. The host device may be an external processor, such as a microprocessor. Similarly, the column decoder 112 may receive a column address CADD from the memory controller 114 and may activate the appropriate digit line 108 based on the column address CADD. The column decoder 112 may activate one or more column selection circuits via one or more column select lines (CSLs). Thus, the column decoder 112 may include a plurality of column select (CS) drivers, with each CS driver configured to drive a respective CSL. The column decoder 112 may be arranged at one side of the memory array 102 (e.g., on one side of the bank). The column decoder 112 may decode the column address CADD and may output a column select signal CSS to the memory array 102 according to the decoding result.

Upon accessing a memory cell 104, the memory cell 104 may be read (e.g., sensed) by a sense component 116 to determine the stored data state of the memory cell 104. For example, after accessing the memory cell 104, the capacitor of the memory cell 104 may discharge onto its corresponding digit line 108. Discharging the capacitor may be based on biasing, or applying a voltage, to the capacitor. The discharging may induce a change in the voltage of the digit line 108, which the sense component 116 may compare to a reference voltage (not shown) to determine the stored data state of the memory cell 104. For example, if the digit line 108 has a higher voltage than the reference voltage, then the sense component 116 may determine that the stored data state of the memory cell 104 corresponds to a first value, such as a binary 1. Conversely, if the digit line 108 has a lower voltage than the reference voltage, then the sense component 116 may determine that the stored data state of the memory cell 104 corresponds to a second value, such as a binary 0. The detected data state of the memory cell 104 may then be output (e.g., via the column decoder 112) to an output component 118 (e.g., a data buffer). A memory cell 104 may be written (e.g., set) by activating the appropriate access line 106 and digit line 108. The column decoder 112 may receive data, such as input from input component 120, to be written to one or more memory cells 104. A memory cell 104 may be written by applying a voltage across the capacitor of the memory cell 104.

The sense component 116 may be a read-write gap circuit associated with the memory array 102. The read-write gap circuit may include a sense amplifier circuit configured to read data from the memory array 102. For example, the sense amplifier circuit may include one or more sense amplifiers. In some implementations, the sense amplifier circuit may be a PNSA circuit. A PNSA is a local sense amplifier used to detect and amplify the differential voltage in a particular direction or polarity. In the context of differential amplifiers, this often means amplifying the difference where one digit line is lower than another digit line. In a DRAM read operation, a stored charge on the capacitor of a memory cell may be sensed, which creates a differential voltage across the digit lines. A PNSA may be configured to detect and amplify the differential voltage to a full logic level, making the data readable. Thus, the PNSA of the sense component 116 may detect a small differential signal and amplify the small differential signal, effectively determining whether stored data represents a logic ‘0’ or a logic ‘1’.

The output component 118 and the input component 120 may form a data input/output (I/O) circuit 122 that may output data DQ from the memory array 102 to the external processor during a read operation or may input data DQ from the external processor to the memory array 102 during a write operation. The data I/O circuit 122 may be arranged adjacent to the column decoder 112 for quick access to the column decoder 112.

The output component 118 may include a DSA that is coupled to global I/O lines of the memory device 100, and an output driver. The DSA part of circuitry responsible for processing and driving the data between the memory array 102 and an external interface, such as DQ data lines. The DSA may amplify small voltage differences present on the global I/O lines. The voltage differences on the global I/O lines represent the data read from the memory cells after being transferred through local I/O lines and the sense amplifiers of the sense component 116. The output driver may generate output data based on the amplified difference between the differential pair of GIO lines provided by the DSA. The DSA ensures that the differential signals are strong enough to be reliably detected and processed by the output driver or other parts of the I/O circuit. Beyond amplification, the DSA may also condition the differential signals, which may include cleaning up the differential signals, reducing noise, and ensuring proper voltage levels for subsequent stages in the I/O circuit. Once the data signals are amplified and conditioned, the DSA may drive these data signals to the output buffers or drivers, which then transmit the data to the DQ data lines.

The data I/O circuit 122 may by coupled to DQ data lines that connect the memory device 100 to a memory controller or other external components. Thus, the DQ data lines may be configured to carry data between the memory device 100 and the memory controller. The DQ data lines may be the primary means by which data is read from or written to the memory device 100 by the host device. The DQ data lines can use a variety of signaling methods, including single-ended and differential signaling. In modern high-speed DRAM standards, such as DDR3, DDR4, and DDR5, differential signaling (such as DQ/DQS for data strobe signals) may be used to improve signal integrity and reduce noise.

The memory controller 114 may control the operation (e.g., read, write, re-write, refresh, and/or recovery) of the memory cells 104 via the row decoder 110, the column decoder 112, and/or the sense component 116. The memory controller 114 may generate row address signals and column address signals to activate the desired access line 106 and digit line 108. The memory controller 114 may also generate and control various voltages used during the operation of the memory array 102.

As indicated above, FIG. 1 is provided as an example. Other examples may differ from what is described with respect to FIG. 1.

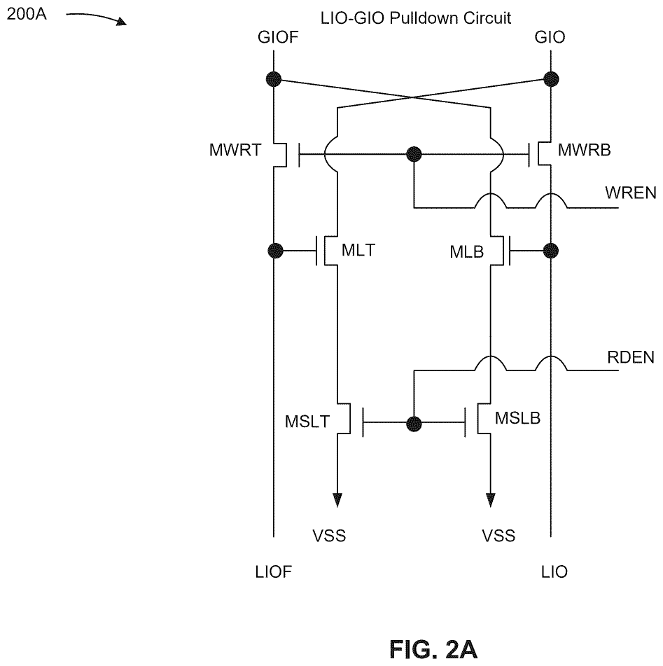

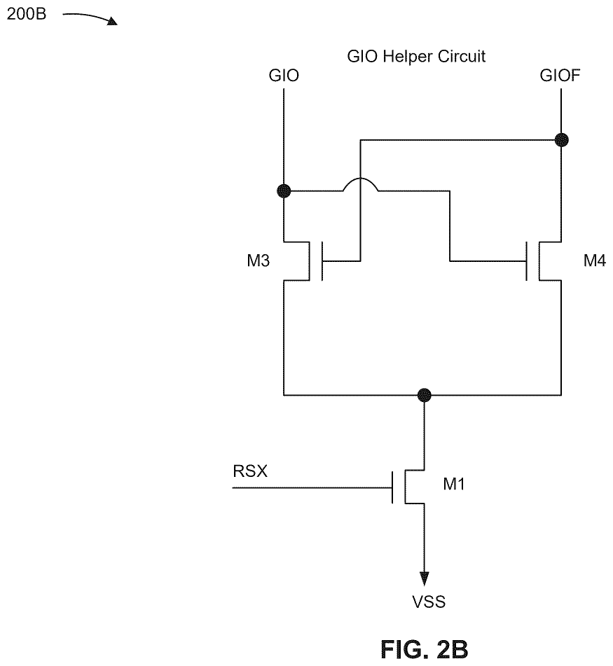

FIG. 2A shows a schematic diagram of an LIO-GIO pulldown circuit 200A according to one or more implementations. The LIO-GIO pulldown circuit 200A may be part of the sense component 116 described in connection with FIG. 1. For example, the LIO-GIO pulldown circuit 200A be integrated in a read-write gap circuit associated with the memory array 102. More particularly, the LIO-GIO pulldown circuit 200A may be part of a sense amplifier circuit configured to read data from the memory array 102. In some implementations, the sense amplifier circuit may be a PNSA circuit. For example, the LIO-GIO pulldown circuit 200A may be a PNSA.

As explained above in connection with FIG. 1, the data I/O circuit 122 may transmit output data from the memory device 100 corresponding to read data received from the memory array 102. The memory device 100 may include a differential pair of GIO lines configured to transfer the read data from the sense component 116 (e.g., from the sense amplifier circuit) to the data I/O circuit 122. For example, the differential pair of GIO lines may include a global I/O line GIO and a global I/O line GIOF, which is a complement of the global I/O line GIO. In addition, the memory device 100 may include a plurality of LIO lines configured to receive respective read data from the plurality of data lines coupled to the memory array 102. The plurality of LIO lines may include a differential pair of LIO lines corresponding to a respective data line and configured to receive the read data from the respective data line. For example, the differential pair of LIO lines may include a local I/O line LIO and a local I/O line LIOF, which is a complement of the local I/O line LIO. This local-global I/O framework allows for a scalable architecture that maintains signal integrity and reduces propagation delay across the memory array 102. An LIO line may be coupled to a respective data line through a respective column select (CS) transistor. For example, a CS transistor may connect a data line (DL) and an LIO line based on a column address CADD received by the column decoder 112.

The LIO-GIO pulldown circuit 200A is coupled to the differential pair of LIO lines at an input side and coupled to the differential pair of GIO lines at an output side. Thus, the LIO-GIO pulldown circuit 200A may transfer read data from the differential pair of LIO lines to the differential pair of GIO lines. In addition, the LIO-GIO pulldown circuit 200A may amplify the difference between the differential pair of GIO lines.

The global I/O line GIOF and the global I/O line GIO are arranged on opposite, complementary sides of the LIO-GIO pulldown circuit 200A. Likewise, the local I/O line LIOF and the local I/O line LIO are arranged on opposite, complementary sides of the LIO-GIO pulldown circuit 200A. As a result, global I/O line GIOF and the local I/O line LIO are arranged on opposite, complementary sides of the LIO-GIO pulldown circuit 200A, and the global I/O line GIO and the local I/O line LIOF are arranged on opposite, complementary sides of the LIO-GIO pulldown circuit 200A. Thus, the global I/O line GIOF and the local I/O line LIOF are arranged on a same side of the LIO-GIO pulldown circuit 200A, and the global I/O line GIO and the local I/O line LIO are arranged on a same side of the LIO-GIO pulldown circuit 200A.

The LIO-GIO pulldown circuit 200A may include n-channel metal-oxide semiconductor (NMOS) transistors, including write enable transistors MWRT and MWRB that are enabled (e.g., turned on) by a write enable signal WREN during a write operation, read enable transistors MSLT and MSLB that are enabled (e.g., turned on) by a first read enable signal RDEN during a read operation, and transistors MLT and MLB. The transistors MLT and MLB may be referred to as pulldown transistors (e.g., of a first plurality of pulldown transistors), with transistor MLT being a first pulldown transistor and transistor MLB being a second pulldown transistor.

The write enable transistor MWRT may directly couple the global I/O line GIOF and the local I/O line LIOF during a write operation such that a GIOF voltage is transferred from the global I/O line GIOF to the local I/O line LIOF. The write enable transistor MWRB may directly couple the global I/O line GIO and the local I/O line LIO during the write operation such that a GIO voltage is transferred from the global I/O line GIO to the local I/O line LIO.

The first read enable signal RDEN may be received at a first read enable input coupled to the control terminals (e.g., gate terminals) of the read enable transistors MSLT and MSLB. Source terminals of the read enable transistors MSLT and MSLB may be coupled to a supply voltage VSS corresponding to a ground potential or a negative potential, which enables a pulldown function. Additionally, transistor MLT includes a control terminal that is coupled to the local I/O line LIOF and a drain terminal that is coupled to the global I/O line GIO. Transistor MLB includes a control terminal that is coupled to the local I/O line LIO and a drain terminal that is coupled to the global I/O line GIOF. Source and drain terminals may be referred to as IO terminals.

Based on the data being read from the memory array 102, the local I/O line LIO may be set to a supply voltage VDD corresponding to a positive potential or to supply voltage VSS. Conversely, the local I/O line LIOF may be set to the complement of the local I/O line LIO. Put another way, when the local I/O line LIO is set to VDD, the local I/O line LIOF is set to VSS, which may correspond to a logical ‘1’ data value. When the local I/O line LIO is set to VSS, the local I/O line LIOF is set to VDD, which may correspond to a logical ‘0’ data value.

The first pulldown transistor MLT has a first control gate couple to a first LIO line (LIOF) of the differential pair of LIO lines and a first IO terminal (e.g., a drain terminal) coupled to a first GIO line (GIO) of the differential pair of GIO lines. The second pulldown transistor MLB has a second control gate couple to a second LIO line (LIO) of the differential pair of LIO lines and a second IO terminal (e.g., a drain terminal) coupled to a second GIO line (GIOF) of the differential pair of GIO lines. A first LIO voltage on the first LIO line (LIOF) causes the first pulldown transistor MLT to pull down the first GIO line (GIO) such that the difference between the differential pair of GIO lines (GIO, GIOF) is increased. A second LIO voltage on the second LIO line (LIO) causes the second pulldown transistor MLB to pull down the second GIO line (GIOF) such that the difference between the differential pair of GIO lines (GIO, GIOF) is increased. The first LIO line (LIOF) may be configured to provide a first LIO voltage to the first control gate of the first pulldown transistor MLT, and, based on the first LIO voltage exceeding a threshold voltage of the first pulldown transistor MLT, the first pulldown transistor MLT may be configured to pull down the first GIO line (GIO) such that the difference between the differential pair of GIO lines (GIO, GIOF) is increased. The second LIO line (LIO) is configured to provide a second LIO voltage to the second control gate of the second pulldown transistor MLB, and, based on the second LIO voltage exceeding a threshold voltage of the second pulldown transistor MLB, the second pulldown transistor MLB may be configured to pull down the second GIO line

(GIOF) such that the difference between the differential pair of GIO lines (GIO, GIOF) is increased.

Assuming that the data being read is logical ‘1’ data value (e.g., LIO is VDD and LIOF is VSS), initially GIO and GIOF are in a precharged state at a VDD level. When the first read enable signal RDEN is received at the control terminals of the read enable transistors MSLT and MSLB, the transistor MSLB will switch on since LIO is at VDD. As a result, the transistor MSLB will pull down GIOF. Meanwhile, GIO is still at VDD because LIOF is at VSS. As a result, a difference between GIO and GIOF is increased, thereby amplifying the difference between GIO and GIOF.

Assuming that the data being read is logical ‘0’ data value (e.g., LIO is VSS and LIOF is VDD), initially GIO and GIOF are in a precharged state at the VDD level. When the first read enable signal RDEN is received at the control terminals of the read enable transistors MSLT and MSLB, the transistor MSLT will switch on since LIOF is at VDD. As a result, the transistor MSLT will pull down GIO. Meanwhile, GIOF is still at VDD because LIO is at VSS. As a result, a difference between GIO and GIOF is increased, thereby amplifying the difference between GIO and GIOF.

As indicated above, FIG. 2A is provided as an example. Other examples may differ from what is described with respect to FIG. 2A.

FIG. 2B shows a schematic diagram of a GIO helper circuit 200B according to one or more implementations. The GIO helper circuit 200B may be part of the sense component 116 described in connection with FIG. 1. For example, the GIO helper circuit 200B be integrated in a read-write gap circuit associated with the memory array 102. More particularly, the GIO helper circuit 200B may be part of a sense amplifier circuit configured to read data from the memory array 102. In some implementations, the sense amplifier circuit may be a PNSA circuit. The GIO helper circuit 200B may be coupled to the differential pair of GIO lines GIO and GIOF and to the supply voltage VSS. The GIO helper circuit 200B may be configured to amplify the difference between the differential pair of GIO lines GIO and GIOF. Thus, the GIO helper circuit 200B may assist or otherwise help the LIO-GIO pulldown circuit 200A increase the difference between GIO and GIOF. The GIO helper circuit 200B is not coupled to the LIO lines LIO and LIOF.

The GIO helper circuit 200B may include NMOS transistors, including a read enable transistor M1 that is enabled (e.g., turned on) by a second read enable signal RSX, and a pair of NMOS cross-coupled transistors M3 and M4 configured to further amplify the difference between the differential pair of GIO lines GIO and GIOF. Thus, the GIO helper circuit 200B may include a cross-coupled transistor circuit configured to increase the differential voltage of the differential pair of GIO lines GIO and GIOF to generate an amplified differential voltage. The transistors M3 and M4 may be referred to as pulldown transistors (e.g., of a second plurality of pulldown transistors), with transistor M3 being a third pulldown transistor and transistor M4 being a fourth pulldown transistor.

The third pulldown transistor M3 has a third control gate coupled to the second GIO line (GIOF) and a third IO terminal (e.g., a drain terminal) coupled to the first GIO line (GIO). The fourth pulldown transistor M4 has a fourth control gate coupled to the first GIO line (GIO) and a fourth IO terminal (e.g., a drain terminal) coupled to the second GIO line (GIOF). The first GIO line (GIO) may be configured to provide a first GIO voltage to the fourth control gate of the fourth pulldown transistor M4, and, based on the first GIO voltage exceeding a threshold voltage of the fourth pulldown transistorM4, the fourth pulldown transistor M4 may be configured to pull down the second GIO line (GIOF) such that the difference between the differential pair of GIO lines (GIO, GIOF) is increased. The second GIO line (GIOF) may be configured to provide a second GIO voltage to the third control gate of the third pulldown transistor M3, and, based on the second GIO voltage exceeding a threshold voltage of the third pulldown transistor M3, the third pulldown transistor M3 may be configured to pull down the first GIO line (GIO) such that the difference between the differential pair of GIO lines (GIO, GIOF) is increased.

The second read enable signal RSX may be received at a second read enable input coupled to the control terminal of the read enable transistor M1. The source terminal of the read enable transistor M1 may be coupled to the supply voltage VSS, which enables a pulldown function while the read enable transistor M1 is enabled. By amplifying the difference between GIO and GIOF, the GIO helper circuit 200B is configured to reduce a data access time for reading out the read data from the memory array 102 to a data I/O line of the data I/O circuit 122. Put another way, the GIO helper circuit 200B may reduce a delay in providing the read data from the memory array 102 to the data I/O circuit 122.

Assuming that the data being read is logical ‘1’ data value (e.g., LIO is VDD and LIOF is VSS), initially GIO and GIOF are in a precharged state at the VDD level. When the first read enable signal RDEN is received at the control terminals of the read enable transistors MSLT and MSLB of the LIO-GIO pulldown circuit 200A, the transistor MSLB will switch on to pulldown GIOF, as described above.

Additionally, when the second read enable signal RSX is received at the control terminal of the read enable transistor M1, the read enable transistor M1 turns on. The second read enable signal RSX may be transmitted with a delay relative to the first read enable signal RDEN such that the second read enable signal RSX is received after the first read enable signal RDEN to ensure that the pulldown function has been performed by the LIO-GIO pulldown circuit 200A.

When the second read enable signal RSX is received, GIO is still at VDD and GIOF is now less than VDD as a result of the pulldown function performed by the LIO-GIO pulldown circuit 200A. For example, GIOF may be at VDDdelta. As a result, transistor M4 is strongly turned on compared to transistor M3 because a gate voltage of transistor M4 (e.g., VDD) is higher than that of the gate voltage of transistor M3 (e.g., VDDdelta). As a result, transistor M4 pulls GIOF even further down, while GIO is relatively constant with respect to an initial precharge level VDD. As a result, the difference between GIO and GIOF is further increased, thereby further amplifying the difference between GIO and GIOF. By controlling a pulse width of the second read enable signal RSX, the amplification of the difference between GIO and GIOF can be controlled. The second read enable signal RSX and the first read enable signal RDEN may be independently controlled. Thus, pulses of the second read enable signal RSX and the first read enable signal RDEN may be provided at different times and/or for different durations.

Assuming that the data being read is logical ‘0’ data value (e.g., LIO is VSS and LIOF is VDD), initially GIO and GIOF are in a precharged state at the VDD level. When the first read enable signal RDEN is received at the control terminals of the read enable transistors MSLT and MSLB of the LIO-GIO pulldown circuit 200A, the transistor MSLT will switch on to pulldown GIO, as described above.

Additionally, when the second read enable signal RSX is received at the control terminal of the read enable transistor M1, the read enable transistor M1 turns on. The second read enable signal RSX may be transmitted with a delay relative to the first read enable signal RDEN such that the second read enable signal RSX is received after the first read enable signal RDEN to ensure that the pulldown function has been performed by the LIO-GIO pulldown circuit 200A.

When the second read enable signal RSX is received, GIOF is still at VDD and GIO is now less than VDD as a result of the pulldown function performed by the LIO-GIO pulldown circuit 200A. For example, GIO may be at VDDdelta. As a result, transistor M3 is strongly turned on compared to transistor M4 because a gate voltage of transistor M3 (e.g., VDD) is higher than that of the gate voltage of transistor M4 (e.g., VDDdelta). As a result, transistor M3 pulls GIO even further down, while GIOF is relatively constant with respect to an initial precharge level VDD. As a result, the difference between GIO and GIOF is further increased, thereby further amplifying the difference between GIO and GIOF. By controlling a pulse width of the second read enable signal RSX, the amplification of the difference between GIO and GIOF can be controlled.

The LIO-GIO pulldown circuit 200A and the GIO helper circuit 200B may be provided in each sense amplifier block (e.g., each PNSA region) of the memory device, with each sense amplifier block being associated with a different memory array or memory core. Moreover, one or more additional GIO helper circuits 200B may be enabled along the differential pair of GIO lines GIO and GIOF for effective signal development between GIO and GIOF. The GIO helper circuit 200B can be utilized to enhance the voltage differential on the GIO lines, thus improving the speed of data sensing. For example, the GIO helper circuit 200B, when activated, may further amplify this voltage differential to a level where the data can be read more rapidly and accurately, which is particularly useful for large-capacity DRAM where speed is important. The GIO helper circuit 200B may configured to boost signal margins necessary for subsequent stages of sensing.

As indicated above, FIG. 2B is provided as an example. Other examples may differ from what is described with respect to FIG. 2B.

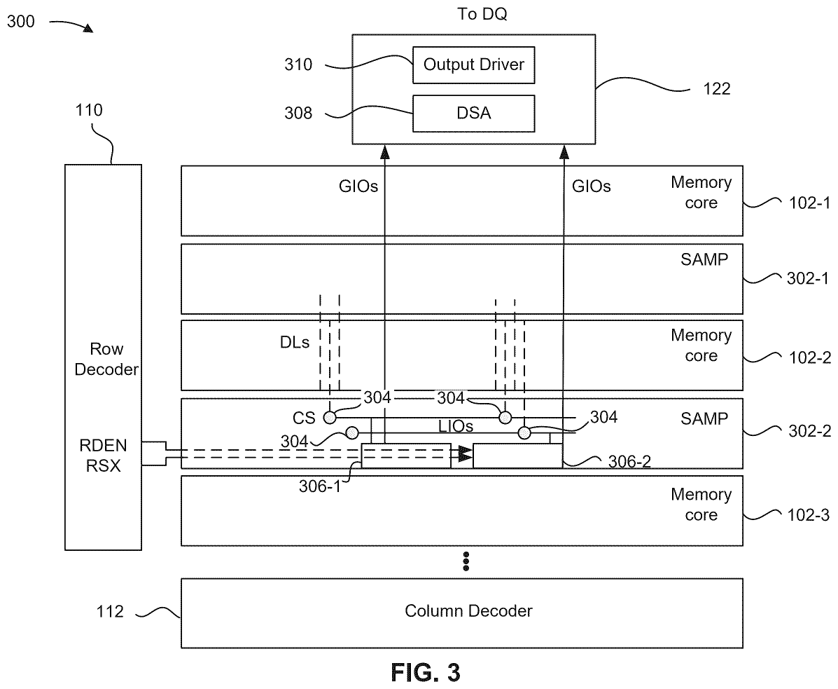

FIG. 3 shows a memory device 300 according to one or more implementations. The memory device 300 may be similar to the memory device 100 described in connection with FIG. 1. The memory device 300 may include the row decoder 110, the column decoder 112, and the data I/O circuit 122. In addition, the memory device 300 may include a plurality of memory arrays 102-1, 102-2 and 102-3 that are similar to memory array 102 described in connection with FIG. 1. Each memory array 102-1, 102-2 and 102-3 may be a memory core of the memory device 300. In addition, the memory device 300 may include a plurality of sense amplifier circuit (SAMP) 302-1, 302-2, Each sense amplifier circuit 302 may be associated with a respective memory array 102 of the plurality of memory arrays for reading read data from the respective memory array 102. For example, the sense amplifier circuit 302-1 may be configured to read data from the memory array 102-1, and the sense amplifier circuit 302-2 may be configured to read data from the memory array 102-2.

An LIO line may be coupled to a respective data line (DL) through a respective CS transistor 304. For example, a CS transistor 304 may connect a DL and an LIO line based on a column address CADD received by the column decoder 112. Thus, the CS transistor 304 may transfer data from a DL to an LIO.

Each sense amplifier circuit 302 may include one or more respective read-write gap circuits 306-1 and 306-2. Each respective read-write gap circuit 306-1 and 306-2 may include a respective a LIO-GIO pulldown circuit and a respective GIO helper circuit. Each respective LIO-GIO pulldown circuit may be similar to the LIO-GIO pulldown circuit 200A described in connection with FIG. 2A. Each respective GIO helper circuit may be similar to the GIO helper circuit 200B described in connection with FIG. 2B. Each read-write gap circuit 306 may be coupled to the data I/O circuit 122 by a respective differential pair of GIO lines.

The respective LIO-GIO pulldown circuit of each sense amplifier circuit 302 may be configured to transfer the read data from a respective differential pair of LIO lines to a respective differential pair of GIO lines. Additionally, respective LIO-GIO pulldown circuit of each sense amplifier circuit 302 may amplify a difference between the respective differential pair of GIO lines. Furthermore, the respective GIO helper circuit of each sense amplifier circuit 302 may further amplify the difference between the respective differential pair of GIO lines.

The row decoder 110 may provide the first read enable signal RDEN and the second read enable signal RSX to the respective read-write gap circuits 306-1 and 306-2 for enabling read operations. Each respective LIO-GIO pulldown circuit is configured to be selectively enabled by a respective first read enable signal RDEN. Each respective GIO helper circuit is configured to be selectively enabled by a respective second read enable signal RSX.

The data I/O circuit 122 may include a data sense amplifier 308 and an output driver 310. The data sense amplifier 308 may further amplify the difference between differential pair of GIO lines. The output driver 310 may generate the output data for the DQ data lines based on the amplified difference between the differential pair of GIO lines provided by the data sense amplifier 308.

As indicated above, FIG. 3 is provided as an example. Other examples may differ from what is described with respect to FIG. 3.

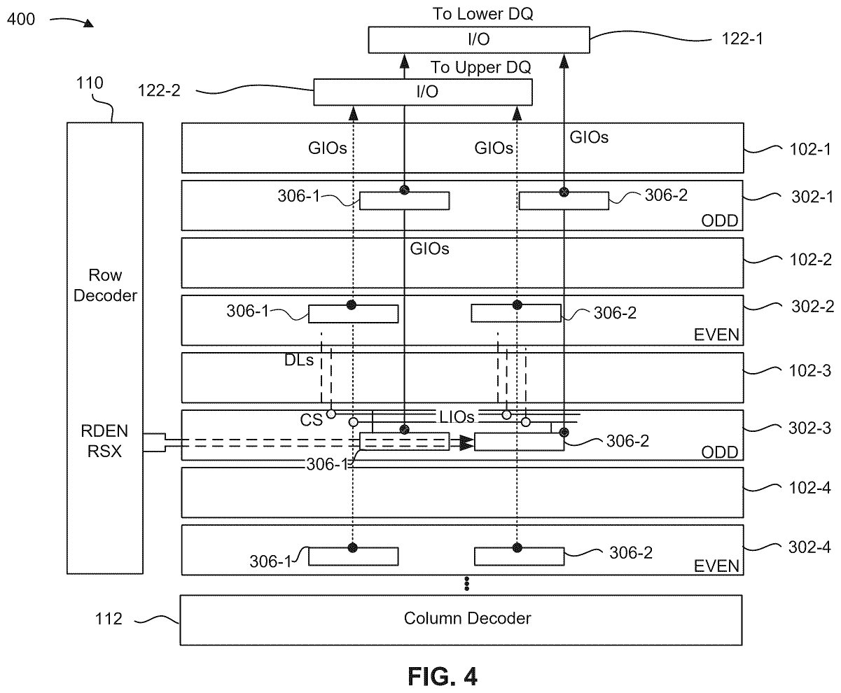

FIG. 4 shows a memory device 400 according to one or more implementations. The memory device 400 may be similar to the memory device 300 described in connection with FIG. 3. However, memory device 400 may include two data I/O circuits 122-1 and 122-2 for different sets of DQ data lines. For example, the data I/O circuit 122-1 may be coupled to lower DQ data lines and data I/O circuit 122-2 may be coupled to upper DQ data lines. The data I/O circuits 122-1 and 122-2 may be similar in structure to the data I/O circuit 122 described in connection with FIG. 3. Thus, the data I/O circuits 122-1 and 122-2 may each include a DSA and an output driver, which may be integrated in an output component (e.g., output component 118). In addition, the data I/O circuit 122-1 may be coupled odd-numbered sense amplifier circuits 302 (e.g., sense amplifier circuits 302-1 and 302-3) by corresponding GIO lines, and the data I/O circuit 122-2 may be coupled even-numbered sense amplifier circuits 302 (e.g., sense amplifier circuits 302-2 and 302-4) by corresponding GIO lines. The odd-numbered sense amplifier circuits 302 may be interleaved or alternated with the even-numbered sense amplifier circuits 302. Moreover, there may be an equal number of odd-numbered sense amplifier circuits 302 and even-numbered sense amplifier circuits 302.

Each sense amplifier circuit 302 may be associated with a respective memory array 102 of the plurality of memory arrays for reading read data from the respective memory array 102. For example, the sense amplifier circuit 302-1 may be configured to read data from the memory array 102-1, the sense amplifier circuit 302-2 may be configured to read data from the memory array 102-2, the sense amplifier circuit 302-3 may be configured to read data from the memory array 102-3, and the sense amplifier circuit 302-4 may be configured to read data from the memory array 102-4. Additional memory arrays 102 and sense amplifier circuits 302 may be provided. Each sense amplifier circuit 302 may have a similar structure described in connection with FIG. 3, including one or more respective read-write gap circuits 306-1 and 306-2. Each respective read-write gap circuit 306-1 and 306-2 may include a respective a LIO-GIO pulldown circuit and a respective GIO helper circuit, as described above.

Read-write gap circuits 306-1 of even-numbered sense amplifier circuits 302 may be coupled together by corresponding GIO lines. Similarly, read-write gap circuits 306-2 of even-numbered sense amplifier circuits 302 may be coupled together by corresponding GIO lines, read-write gap circuits 306-1 of odd-numbered sense amplifier circuits 302 may be coupled together by corresponding GIO lines, and read-write gap circuits 306-2 of odd-numbered sense amplifier circuits 302 may be coupled together by corresponding GIO lines. One or more GIO helper circuits arranged downstream from another GIO helper circuit of a sense amplifier circuit 302 performing a read operation may be used to further amplify a difference between a respective differential pair of GIO lines.

Here, “downstream” means between a sense amplifier circuit 302 performing a read operation and a data I/O circuit 122. A read-write gap circuit arranged downstream from another read-write gap circuit on the same differential pair of GIO lines may be referred to as a further read-write gap circuit, which may include a further GIO helper circuit that may be enabled by a second read enable signal RSX in order to assist in transferring a differential voltage to a DSA along the differential pair of GIO lines. Thus, sense amplifier circuit 302-1 is arranged downstream from sense amplifier circuit 302-3, and sense amplifier circuit 302-2 is arranged downstream from sense amplifier circuit 302-4. Thus, the GIO helper circuit of the read-write gap circuit 306-1 of sense amplifier circuit 302-1 is arranged downstream from the read-write gap circuit 306-1 of sense amplifier circuit 302-3 and may be used to help the read-write gap circuit 306-1 of sense amplifier circuit 302-3 further amplify the difference between the differential pair of GIO lines originating from the read-write gap circuit 306-1 of sense amplifier circuit 302-3. Thus, the GIO helper circuit of the read-write gap circuit 306-1 of sense amplifier circuit 302-1 may be enabled when the GIO helper circuit of the read-write gap circuit 306-1 of sense amplifier circuit 302-3 is enabled in order to boost signal development and help the read-write gap circuit 306-1 of sense amplifier circuit 302-3 provide a strong differential voltage to the data I/O circuit 122-1.

Similarly, the GIO helper circuit of the read-write gap circuit 306-1 of sense amplifier circuit 302-2 is arranged downstream from the read-write gap circuit 306-1 of sense amplifier circuit 302-4 and may be used to help the read-write gap circuit 306-1 of sense amplifier circuit 302-4 further amplify the difference between the differential pair of GIO lines originating from the read-write gap circuit 306-1 of sense amplifier circuit 302-4. Thus, the GIO helper circuit of the read-write gap circuit 306-1 of sense amplifier circuit 302-2 may be enabled when the GIO helper circuit of the read-write gap circuit 306-1 of sense amplifier circuit 302-4 is enabled in order to help the read-write gap circuit 306-1 of sense amplifier circuit 302-4 provide a strong differential voltage to the data I/O circuit 122-2.

Accordingly, one or more GIO helper circuits coupled to a same differential pair of GIO lines (e.g., GIO and GIOF) may be used in conjunction with each other to increase the differential voltage between the differential pair of GIO lines. In other words, while one GIO helper circuit may be associated with a particular sense amplifier circuit 302 that is configured to sense data from a particular memory array 102, another GIO helper circuit associated with a different sense amplifier circuit 302 of a different memory array 102 may be used to further amplify the differential voltage between the differential pair of GIO lines so long as the other GIO helper circuit is coupled to the same differential pair of GIO lines. As a result, a series of GIO helper circuits along the differential pair of GIO lines may be used to ensure that the differential voltage between the differential pair of GIO lines is maintained strong enough to enable a DSA to properly output a signal to rail voltages. For example, a GIO helper circuit may be implemented in PNSA section of a distributed read driver architecture. The GIO helper circuits along the differential pair of GIO lines may be used to maintain a voltage difference or a PNSA height between the differential pair of GIO lines at an approximately same level along a length of the differential pair of GIO lines, ensuring that a DSA receives a large enough voltage delta on the differential pair of GIO lines to accurately process the voltage difference. The GIO helper circuits may be selectively enabled to reduce analog data timing (e.g., data access time tAA) and improve array efficiency. The GIO helper circuits may reduce a size of the DSAs by enabling the DSAs to be NMOS coupled instead of cross-coupled. The GIO helper circuits may enable larger DRAM sizes, including DRAM sizes greater than 16 Gb. Moreover, the GIO helper circuits may enable may be scalable to larger DRAM sizes without adding additional peripheral circuitry or changes in memory array architecture.

As indicated above, FIG. 4 is provided as an example. Other examples may differ from what is described with respect to FIG. 4.

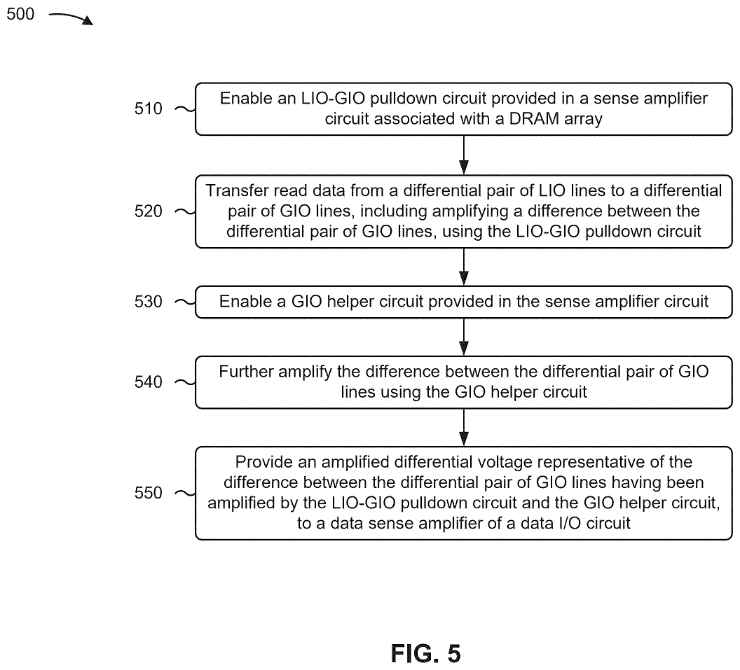

FIG. 5 is a flowchart of an example method 500 associated with distributed read driver for data sensing in DRAM. In some implementations, a memory device (e.g., the memory device 100, 300, or 400) may perform or may be configured to perform the method 500. Additionally, or alternatively, one or more components of the memory device (e.g., the row decoder 110, the column decoder 112, the memory controller 114, the sense component 116, and/or the data I/O circuit 122) may perform or may be configured to perform the method 500. Thus, means for performing the method 500 may include the memory device and/or one or more components of the memory device. Additionally, or alternatively, a non-transitory computer-readable medium may store one or more instructions that, when executed by the memory device (e.g., the controller 114 of the memory device 100), cause the memory device to perform the method 500.

As shown in FIG. 5, the method 500 may include enabling an LIO-GIO pulldown circuit provided in a sense amplifier circuit associated with a DRAM array (block 510). As further shown in FIG. 5, the method 500 may include transferring read data from a differential pair of LIO lines to a differential pair of GIO lines, including amplifying a difference between the differential pair of GIO lines, using the LIO-GIO pulldown circuit (block 520). As further shown in FIG. 5, the method 500 may include enabling a GIO helper circuit provided in the sense amplifier circuit (block 530). As further shown in FIG. 5, the method 500 may include further amplifying the difference between the differential pair of GIO lines using the GIO helper circuit (block 540). As further shown in FIG. 5, the method 500 may include providing an amplified differential voltage representative of the difference between the differential pair of GIO lines having been amplified by the LIO-GIO pulldown circuit and the GIO helper circuit, to a data sense amplifier of a data I/O circuit (block 550).

The method 500 may include additional aspects, such as any single aspect or any combination of aspects described below and/or described in connection with one or more other methods or operations described elsewhere herein.

In a first aspect, the method 500 includes enabling, by the memory controller, a further GIO helper circuit provided in a further sense amplifier circuit associated with a further DRAM array, and basing on the further GIO helper circuit being enabled, further amplifying, by the further GIO helper circuit, the difference between the differential pair of GIO lines.

Although FIG. 5 shows example blocks of a method 500, in some implementations, the method 500 may include additional blocks, fewer blocks, different blocks, or differently arranged blocks than those depicted in FIG. 5. Additionally, or alternatively, two or more of the blocks of the method 500 may be performed in parallel. The method 500 is an example of one method that may be performed by one or more devices described herein. These one or more devices may perform or may be configured to perform one or more other methods based on operations described herein.

In some implementations, a memory device includes a memory array that includes a plurality of data lines and a plurality of memory cells respectively coupled to the plurality of data lines; a data I/O circuit configured to transmit output data from the memory device corresponding to read data received from the memory array; a differential pair of GIO lines configured to transfer the read data to the data I/O circuit; a plurality of LIO lines configured to receive respective read data from the plurality of data lines, wherein the plurality of LIO lines includes a differential pair of LIO lines corresponding to a respective data line and configured to receive the read data from the respective data line; and a read-write gap circuit comprising an LIO-GIO pulldown circuit and a GIO helper circuit, wherein the LIO-GIO pulldown circuit is configured to transfer the read data from the differential pair of LIO lines to the differential pair of GIO lines, wherein the LIO-GIO pulldown circuit is configured to amplify a difference between the differential pair of GIO lines, and wherein the GIO helper circuit is configured to further amplify the difference between the differential pair of GIO lines.

In some implementations, a memory device includes a plurality of memory arrays; and a plurality of sense amplifier circuits, wherein each sense amplifier circuit is associated with a respective memory array of the plurality of memory arrays for reading read data from the respective memory array, wherein each sense amplifier circuit includes a respective an LIO-GIO pulldown circuit and a respective GIO helper circuit, wherein the respective LIO-GIO pulldown circuit of each sense amplifier circuit is configured to transfer the read data from a respective differential pair of LIO lines to a respective differential pair of GIO lines, wherein the respective LIO-GIO pulldown circuit of each sense amplifier circuit is configured to amplify a difference between the respective differential pair of GIO lines, and wherein the respective GIO helper circuit of each sense amplifier circuit is configured to further amplify the difference between the respective differential pair of GIO lines.

In some implementations, a method of performing a read operation from a DRAM device includes enabling, by a memory controller, an LIO-GIO pulldown circuit provided in a sense amplifier circuit associated with a DRAM array; based on the LIO-GIO pulldown circuit being enabled, transferring, by the LIO-GIO pulldown circuit, read data from a differential pair of LIO lines to a differential pair of GIO lines, including amplifying a difference between the differential pair of GIO lines; enabling, by the memory controller, a GIO helper circuit provided in the sense amplifier circuit; based on the GIO helper circuit being enabled, further amplifying, by the GIO helper circuit, the difference between the differential pair of GIO lines; and providing, by the differential pair of GIO lines, an amplified differential voltage representative of the difference between the differential pair of GIO lines having been amplified by the LIO-GIO pulldown circuit and the GIO helper circuit, to a data sense amplifier of a data I/O circuit.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, the terms “substantially” and “approximately” mean “within reasonable tolerances of manufacturing and measurement.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising:
a memory array that includes a plurality of data lines and a plurality of memory cells respectively coupled to the plurality of data lines;
a data input/output (I/O) circuit configured to transmit output data from the memory device corresponding to read data received from the memory array;
a differential pair of global I/O (GIO) lines configured to transfer the read data to the data I/O circuit;
a plurality of local I/O (LIO) lines configured to receive respective read data from the plurality of data lines, wherein the plurality of LIO lines includes a differential pair of LIO lines corresponding to a respective data line and configured to receive the read data from the respective data line; and
a read-write gap circuit comprising an LIO-GIO pulldown circuit and a GIO helper circuit,
wherein the LIO-GIO pulldown circuit is configured to transfer the read data from the differential pair of LIO lines to the differential pair of GIO lines,
wherein the LIO-GIO pulldown circuit is configured to amplify a difference between the differential pair of GIO lines, and
wherein the GIO helper circuit is configured to further amplify the difference between the differential pair of GIO lines.

2. The memory device of claim 1, wherein the GIO helper circuit is coupled to the differential pair of GIO lines and a supply voltage corresponding to a ground potential or a negative potential, and
wherein the LIO-GIO pulldown circuit is coupled to the differential pair of LIO lines, the differential pair of GIO lines, and the supply voltage.

3. The memory device of claim 1, wherein the read-write gap circuit is a p-channel metal-oxide-semiconductor (PMOS)-n-channel metal-oxide-semiconductor (NMOS) sense amplifier sense amplifier (PNSA) circuit arranged in a PNSA circuit region.

4. The memory device of claim 1, wherein the GIO helper circuit includes a cross-coupled transistor circuit configured to increase a differential voltage of the differential pair of GIO lines to generate an amplified differential voltage.

5. The memory device of claim 1, wherein the GIO helper circuit includes a pair of n-channel metal-oxide semiconductor (NMOS) cross-coupled transistors configured to further amplify the difference between the differential pair of GIO lines.

6. The memory device of claim 1, wherein the GIO helper circuit is configured to reduce a data access time for reading out the read data from the memory array to a data I/O line of the data I/O circuit.

7. The memory device of claim 1, wherein the GIO helper circuit is configured to reduce a delay in providing the read data from the memory array to the data I/O circuit.

8. The memory device of claim 1, wherein the data I/O circuit includes an output driver and a data sense amplifier,
wherein the data sense amplifier is configured to further amplify the difference between the differential pair of GIO lines, and
wherein the output driver is configured to generate the output data based on the amplified difference between the differential pair of GIO lines provided by the data sense amplifier.

9. The memory device of claim 8, wherein the data sense amplifier includes n-channel metal-oxide semiconductor (NMOS) coupled transistors.

10. The memory device of claim 8, wherein the read-write gap circuit and the data I/O circuit are coupled by the differential pair of GIO lines.

11. The memory device of claim 1, wherein the memory array is a dynamic random access memory (DRAM) array.

12. The memory device of claim 1, wherein the LIO-GIO pulldown circuit includes a first read enable input configured to receive a first read enable signal,
wherein the GIO helper circuit includes a second read enable input configured to receive a second read enable signal,
wherein the LIO-GIO pulldown circuit is configured to, based on receiving the first read enable signal, amplify the difference between the differential pair of GIO lines, and
wherein the GIO helper circuit is configured to, based on receiving the second read enable signal, further amplify the difference between the differential pair of GIO lines,
wherein the second read enable signal and the first read enable signal are independently controlled.

13. The memory device of claim 1, further comprising:
a further read-write gap circuit comprising a further GIO helper circuit arranged between the GIO helper circuit and the data I/O circuit,
wherein the further GIO helper circuit is configured to further amplify the difference between the differential pair of GIO lines.

14. The memory device of claim 1, wherein the LIO-GIO pulldown circuit includes a first plurality of pulldown transistors including:
a first pulldown transistor having a first control gate couple to a first LIO line of the differential pair of LIO lines and a first IO terminal coupled to a first GIO line of the differential pair of GIO lines; and
a second pulldown transistor having a second control gate couple to a second LIO line of the differential pair of LIO lines and a second IO terminal coupled to a second GIO line of the differential pair of GIO lines,
wherein the first LIO line and the first GIO line are arranged on opposite complementary sides of the LIO-GIO pulldown circuit, and
wherein the second LIO line and the second GIO line are arranged on opposite complementary sides of the LIO-GIO pulldown circuit.

15. The memory device of claim 14, wherein a first LIO voltage on the first LIO line causes the first pulldown transistor to pull down the first GIO line such that the difference between the differential pair of GIO lines is increased, and
wherein a second LIO voltage on the second LIO line causes the second pulldown transistor to pull down the second GIO line such that the difference between the differential pair of GIO lines is increased.

16. The memory device of claim 14, wherein the first LIO line is configured to provide a first LIO voltage to the first control gate, and, based on the first LIO voltage exceeding a threshold voltage of the first pulldown transistor, the first pulldown transistor is configured to pull down the first GIO line such that the difference between the differential pair of GIO lines is increased, and
wherein the second LIO line is configured to provide a second LIO voltage to the second control gate, and, based on the second LIO voltage exceeding a threshold voltage of the second pulldown transistor, the second pulldown transistor is configured to pull down the second GIO line such that the difference between the differential pair of GIO lines is increased.

17. The memory device of claim 14, wherein the GIO helper circuit includes a second plurality of pulldown transistors including:
a third pulldown transistor having a third control gate coupled to the second GIO line and a third IO terminal coupled to the first GIO line; and
a fourth pulldown transistor having a fourth control gate coupled to the first GIO line and a fourth IO terminal coupled to the second GIO line.

18. The memory device of claim 17, wherein the first GIO line is configured to provide a first GIO voltage to the fourth control gate, and, based on the first GIO voltage exceeding a threshold voltage of the fourth pulldown transistor, the fourth pulldown transistor is configured to pull down the second GIO line such that the difference between the differential pair of GIO lines is increased, and
wherein the second GIO line is configured to provide a second GIO voltage to the third control gate, and, based on the second GIO voltage exceeding a threshold voltage of the third pulldown transistor, the third pulldown transistor is configured to pull down the first GIO line such that the difference between the differential pair of GIO lines is increased.

19. The memory device of claim 1, wherein the GIO helper circuit includes a plurality of pulldown transistors including:
a first pulldown transistor having a first control gate coupled to a second GIO line of the differential pair of GIO lines and a first IO terminal coupled to a first GIO line of the differential pair of GIO lines; and
a second pulldown transistor having a second control gate coupled to the first GIO line and a second IO terminal coupled to the second GIO line.

20. The memory device of claim 19, wherein the first GIO line is configured to provide a first GIO voltage to the second control gate, and, based on the first GIO voltage exceeding a threshold voltage of the second pulldown transistor, the second pulldown transistor is configured to pull down the second GIO line such that the difference between the differential pair of GIO lines is increased, and
wherein the second GIO line is configured to provide a second GIO voltage to the first control gate, and, based on the second GIO voltage exceeding a threshold voltage of the first pulldown transistor, the first pulldown transistor is configured to pull down the first GIO line such that the difference between the differential pair of GIO lines is increased.

21. A memory device, comprising:
a plurality of memory arrays; and
a plurality of sense amplifier circuits, wherein each sense amplifier circuit is associated with a respective memory array of the plurality of memory arrays for reading read data from the respective memory array,
wherein each sense amplifier circuit includes a respective a local input/output (LIO)-global input/output (GIO) pulldown circuit and a respective GIO helper circuit,
wherein the respective LIO-GIO pulldown circuit of each sense amplifier circuit is configured to transfer the read data from a respective differential pair of LIO lines to a respective differential pair of GIO lines,
wherein the respective LIO-GIO pulldown circuit of each sense amplifier circuit is configured to amplify a difference between the respective differential pair of GIO lines, and
wherein the respective GIO helper circuit of each sense amplifier circuit is configured to further amplify the difference between the respective differential pair of GIO lines.

22. The memory device of claim 21, further comprising:
a data I/O circuit coupled to the respective differential pair of GIO lines,
wherein each sense amplifier circuit and the data I/O circuit are coupled by the respective differential pair of GIO lines,
wherein the data I/O circuit includes an output driver and a data sense amplifier,
wherein the data sense amplifier is configured to further amplify the difference between the respective differential pair of GIO lines, and
wherein the output driver is configured to generate output data based on the difference between the respective differential pair of GIO lines provided by the data sense amplifier.

23. The memory device of claim 21, wherein each sense amplifier circuit is a p-channel metal-oxide-semiconductor (PMOS)-n-channel metal-oxide-semiconductor (NMOS) sense amplifier sense amplifier (PNSA) circuit arranged in a PNSA circuit region.

24. The memory device of claim 21, wherein each respective GIO helper circuit includes a pair of n-channel metal-oxide semiconductor (NMOS) cross-coupled transistors configured to further amplify the difference between the respective differential pair of GIO lines.

25. The memory device of claim 21, wherein each respective LIO-GIO pulldown circuit is configured to be selectively enabled by a respective first read enable signal, and
wherein each respective GIO helper circuit is configured to be selectively enabled by a respective second read enable signal.

26. A method of performing a read operation from a dynamic random access memory (DRAM) device, the method comprising:
enabling, by a memory controller, a local input/output (LIO)-global input/output (GIO) pulldown circuit provided in a sense amplifier circuit associated with a DRAM array;
based on the LIO-GIO pulldown circuit being enabled, transferring, by the LIO-GIO pulldown circuit, read data from a differential pair of LIO lines to a differential pair of GIO lines, including amplifying a difference between the differential pair of GIO lines;
enabling, by the memory controller, a GIO helper circuit provided in the sense amplifier circuit;
based on the GIO helper circuit being enabled, further amplifying, by the GIO helper circuit, the difference between the differential pair of GIO lines; and
providing, by the differential pair of GIO lines, an amplified differential voltage representative of the difference between the differential pair of GIO lines having been amplified by the LIO-GIO pulldown circuit and the GIO helper circuit, to a data sense amplifier of a data input/output (I/O) circuit.

27. The method of claim 26, further comprising:
enabling, by the memory controller, a further GIO helper circuit provided in a further sense amplifier circuit associated with a further DRAM array; and
based on the further GIO helper circuit being enabled, further amplifying, by the further GIO helper circuit, the difference between the differential pair of GIO lines.
